(19) United States
(12) Patent Application Publication
(10) Pub. No.: US 2008/0303558 A1
(43) Pub. Date: Dec. 11, 2008

(54) DATA OUTPUT DRIVER CIRCUIT

(75) Inventor: Kwang Myoung Rho, Ichon (KR)

Correspondence Address: BAKER & MCKENZIE LLP;PATENT DEPARTMENT, 2001 ROSS AVENUE, SUITE 2300, DALLAS, TX, 75201, US

(73) Assignee: HYNIX SEMICONDUCTOR INC., Ichon (KR)

(21) Appl. No.: 11/958,340

(22) Filed: Dec. 17, 2007

(30) Foreign Application Priority Data
Jun. 11, 2007 (KR) 10-2007-0056935

(51) Int. Cl. H03K 3/00

(52) U.S. Cl. 327/108

(57) ABSTRACT

A data output driver circuit can be configured to comprise a predriver control unit generate a plurality of pullup output load control signals and a plurality of pulldown output load control signals depending upon a sensed external voltage, and a predriver is configured to output a signal by adjusting a slew rate of an inputted data in response to the plurality of pullup output load control signals and the plurality of pulldown output load control signals.

### CROSS-REFERENCES TO RELATED APPLICATION

The present application claims priority under 35 U.S.C. 119(a) to Korean Patent Application number 10-2007-0056935, filed on Jun. 11, 2007, in the Korean Intellectual Property Office, the contents of which are incorporated herein by reference in their entirety as if set forth in full.

### BACKGROUND

1. Technical Field

The embodiments described herein relate to a data output driver circuit, and more particularly, to a data output driver circuit that outputs data by adjusting a slew rate.

2. Related Art

A system operating at a high speed reacts sensitively to the variations in the characteristics of input signals or output signals. That is, as the characteristics of input or output signals vary, system operations may fail due to insufficient timing margin. In particular, variations in process, voltage, and temperature (PVT) can result in changes in the driving capability of a transistor. For example, data output from a data output driver having changed driving capability can have a substantial changed a slew rate. The slew rate defines the maximum change rate of a voltage level of a signal and can be expressed as the slope of voltage with respect to time. The change in slew rate can lead to noise current.

### SUMMARY

According to one aspect, there is provided a data output driver circuit including a predriver control unit configured to generate a plurality of pullup output load control signals and a plurality of pulldown output load control signals depending upon a sensed external voltage, and a predriver configured to output a signal by adjusting a slew rate of received data in response to the plurality of pullup output load control signals and the plurality of pulldown output load control signals.

The predriver control unit can include a PVT sensing part including a transistor configured to sense the external voltage, a voltage comparison part configured to digitize the sensed external voltage and providing comparison signals, and an output load control signal generation part configured to receive and latch the comparison signals and providing the plurality of output load control signals.

According to another aspect, there is provided a data output driver circuit including a predriver control unit configured to sense an external voltage using a transistor capable of monitoring driving characteristics of a predriver and to generate a plurality of pullup output load control signals and a plurality of pulldown output load control signals depending upon the sensed external voltage. The predriver can be configured to change an output load depending upon the driving characteristics in response to the plurality of pullup output load control signals and the plurality of pulldown output load control signals, and to output a signal by adjusting a slew rate of an inputted data.

These and other features, aspects, and embodiments are described below in the section entitled “Detailed Description.”

### BRIEF DESCRIPTION OF THE DRAWINGS

Features, aspects, and embodiments are described in conjunction with the attached drawings, in which:

FIG. 1 is a block diagram illustrating a data output driver circuit in accordance with one embodiment;

FIG. 2 is a circuit diagram illustrating a first predriver that can be included in the circuit illustrated in FIG. 1;

FIG. 3 is a conceptual block diagram illustrating a first predriver control unit that can be included in the circuit illustrated in FIG. 1;

FIG. 4 is a detailed circuit diagram illustrating an output load control signal generation part that can be included in the circuit illustrated in FIG. 3; and

FIG. 5 is a table illustrating output load control signals that are activated by a sensed external voltage and the number of pairs of output loads in accordance with one embodiment.

### DESCRIPTION

By comparing the driving capability of a transistor configured to sense an external voltage upon variations in PVT, the slew rate of an output data signal can be improved. That is to say, an external voltage, which varies in conformity with the variations in PVT, is sensed by a driving transistor, which is substantially the same as the driving transistor included in a data output unit. The sensed external voltage and a predetermined voltage value are compared with each other, and depending upon a comparison result, the activation of pairs of output loads is controlled. In this way, the slew rate of an output data signal can be improved. It is then possible to provide an output data signal that is controlled in slew rate in conformity with variations in PVT.

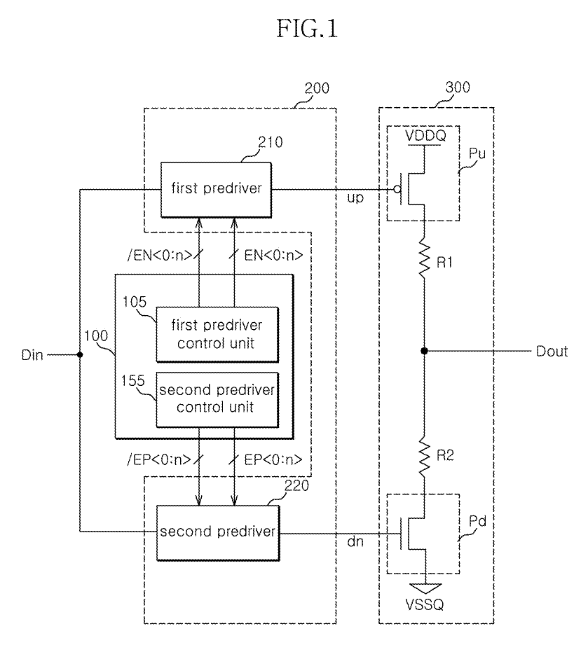

FIG. 1 is a block diagram illustrating a data output driver circuit in accordance with one embodiment. Referring to FIG. 1, a data output driver circuit can include a predriver control unit 100, a predriver 200, and a data output unit 300. The predriver control unit 100 can be configured to generate a plurality of output load control signals (EN<0:n>), (/EN<0:n>), (EP<0:n>) and (/EP<0:n>) in response to a sensed external voltage and to provide the output load control signals to the predriver 200. The predriver control unit 100 can be configured to include first and second predriver control units 105 and 155. The first predriver control unit 105 can be configured to provide the plurality of output load control signals (EN<0:n>) and (/EN<0:n>) to a first predriver 210 in response to the sensed external voltage. The second predriver control unit 155 can be configured to provide the plurality of output load control signals (EP<0:n>) and (/EP<0:n>) to a second predriver 220 in response to the sensed external voltage.

Here, the plurality of output load control signals (EN<0:n>) and (/EN<0:n>) provided to the first predriver 210 can include pulldown output load control signals (EN<0:n>) and pullup output load control signals (/EN<0:n>). Also, the plurality of output load control signals (EP<0:n>) and (/EP<0:n>) provided to the second predriver 220 can include pulldown output load control signals (EP<0:n>) and pullup output load control signals (/EP<0:n>). The pulldown output load control signals (EN<0:n>) and (EP<0:n>) and the pullup output load control signals (/EN<0:n>) and (/EP<0:n>) can be signals that have different logic levels and can control the output signals of the predriver 200.

The predriver 200 can be configured to include the first predriver 210 and the second predriver 200. The first predriver 210 or the second predriver 220 can be configured to operate in response to a received data signal (Din). The first predriver 210 can be configured to control a pullup part (Pu) of the data output unit 300, and the second predriver 220 can be configured to control a pulldown part (Pd) of the data output unit 300.

The first and second predrivers 210 and 220 can be configured to receive the plurality of output load control signals (EN<0:n>), (/EN<0:n>), (EP<0:n>) and (/EP<0:n>), and, in response thereto, adjust the slew rate of a pullup signal (up) or a pulldown signal (dn). The adjustment of the pullup signal (up) or the pulldown signal (dn) will be described later.

The data output unit 300 can be configured to receive the pullup signal (up) or the pulldown signal (dn) and provide an output data (Dout) which can have an improved slew rate. That is, as the pullup signal (up) having an improved slew rate is received, the pullup part (Pu) can provide the output data (Dout) having a driving source voltage level (VDDQ), which can be improved in slew rate. Also, as the pulldown signal (dn) having an improved slew rate is received, the pulldown part (Pd) can provide the output data (Dout) having a ground voltage level (VSSQ), which can be improved in slew rate. The data output unit 300 can further include, but is not limited to, first and second resistors R1 and R2 which can control the slew rate.

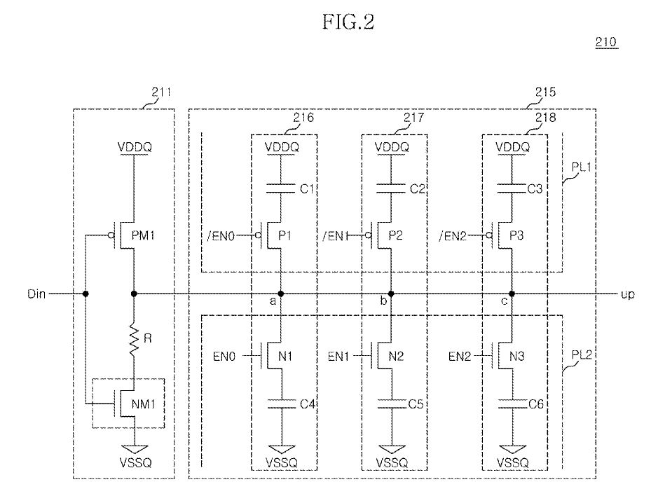

FIG. 2 is a circuit diagram illustrating a first predriver that can be included in the circuit illustrated in FIG. 1. Referring to FIG. 2, the first predriver 210 can be configured to include a data reception part 211 and an output load control part 215. The first predriver 210 can be a pullup driver for controlling the pullup part (Pu) of the data output unit 300.

The data reception part 211 can be configured to include a first PMOS transistor PM1 and a first NMOS transistor NM1. The first PMOS transistor PM1 can include a gate that receives the data (Din), a source that is connected with the driving source voltage (VDDQ), and a drain that is connected with a node a. The first NMOS transistor NM1 can include a gate that receives the data (Din), a source that is connected with the ground voltage (VSSQ), and a drain that is connected with the node a.

The first predriver 210 can be a pullup driver as described above, in particular, the first NMOS transistor NM1 can be a dominant transistor that most influences the slew rate of the output data (Dout) output by the pullup part (Pu). Accordingly, in order to consider the slew rate of the pullup output data (Dout) of the data output unit 300, it is important to reflect the driving characteristics of the first NMOS transistor NM1 upon variations in PVT. Meanwhile, the data reception part 211 can further include, but is not limited to, a resistor R to complement the slew rate of a pullup device.

The output load control part 215 can be configured to include a plurality of pullup and pulldown load section PL1 and PL2, which are connected in parallel. The pullup and pulldown load section PL1 and PL2 can be positioned opposite to each other. The pullup load section PL1 can be configured to operate in response to the pullup output load control signals (/EN<0:2>), and the pulldown load section PL2 can operate in response to the pulldown output load control signals (EN<0:2>).

The pullup load section PL1 can be configured to include a plurality of PMOS transistors P1 through P3. The respective PMOS transistors P1 through P3 can include gates that can respectively receive the plurality of pullup output load control signals (/EN<0:2>), sources that can be connected with the driving source voltage (VDDQ), and drains that can be respectively connected with nodes a through c. Also, the pullup load section PL1 can be configured to include first through third capacitors C1 through C3 between the driving source voltage (VDDQ) and the respective PMOS transistors P1 through P3.

Similarly, the pulldown load section PL2 can be configured to include a plurality of NMOS transistors N1 through N3. The respective NMOS transistors N1 through N3 can include gates that are configured respectively to receive the plurality of pulldown output load control signals (EN<0:2>), sources that are connected with the ground voltage (VSSQ), and drains that are respectively connected with the nodes a through c. Also, the pulldown load section PL2 can include fourth through sixth capacitors C4 through C6 between the ground voltage (VSSQ) and the respective NMOS transistors N1 through N3.

Therefore, the PMOS transistors P1 through P3 can be selectively activated in response to the plurality of pullup output load control signals (/EN<0:2>). The NMOS transistors N1 through N3 can be selectively activated in response to the plurality of pulldown output load control signals (EN<0:2>). Here, the plurality of PMOS transistors P1 through P3 and the NMOS transistors N1 through N3 can be switching elements. In other words, the output load control part 215 can include a plurality of pairs of loads 216 through 218, which can be controlled by the pullup output load control signals (/EN<0:2>) and the pulldown output load control signals (EN<0:2>).

Accordingly, depending upon the activation of the plurality of PMOS transistors P1 through P3 or the NMOS transistors N1 through N3, which can be configured to respond to the plurality of pullup or pulldown output load control signals (/EN<0:2>) or (EN<0:2>), the load of the pullup signal (up) as an output signal can be adjusted by the capacitors C1 through C6, which are connected in series with the PMOS transistors P1 through P3 and the NMOS transistors N1 through N3. Namely, the first predriver 210 can control the slew rate of the pullup signal (up) to become slow, using the RC delays between the PMOS transistors P1 through P3 and the NMOS transistors N1 through N3 and the capacitors C1 through C6 connected in series therewith.

In other words, the magnitude of transition slope of the pullup signal (up) can be adjusted using the number of pairs of PMOS transistors P1 through P3 and NMOS transistors N1 through N3 of the plurality of pairs of output loads 216 through 218, which are simultaneously controlled and activated. Depending upon the configuration of a circuit, that is, the driving capability of the driving transistor, the PMOS transistors P1 through P3 and the NMOS transistors N1 through N3 of the plurality of pairs of output loads 216 through 218 can be provided as pairs of loads having different amounts of load.

The second predriver 220 can have a similar structure to the first predriver 210. Since the second predriver 220 can be a pulldown driver, however, a PMOS transistor (not shown) can be a dominant driving transistor that most influences the slew rate of the pulldown signal (dn).

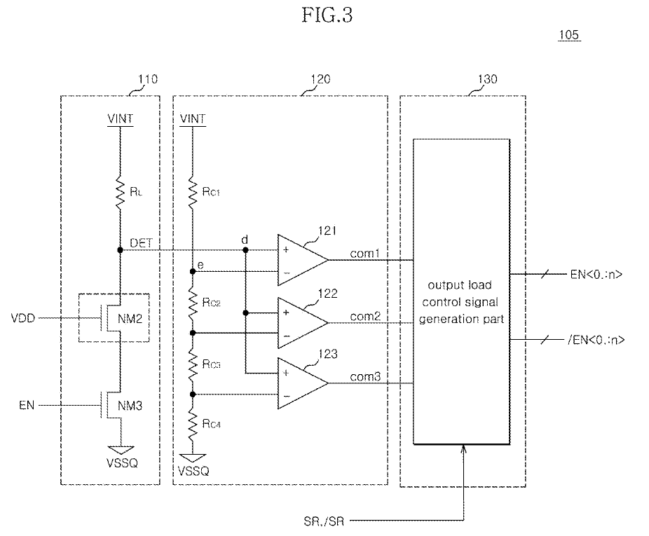

FIG. 3 is a conceptual block diagram illustrating a first predriver control unit that can be included in the circuit illustrated in FIG. 1. Referring to FIG. 3, the first predriver control unit 105 can generates a plurality of output load control signals (EN<0:2>) and (/EN<0:2>) capable of adjusting the magnitude of the transition slope. The illustrated first predriver control unit 105 can monitor the driving characteristics of the first NMOS transistor NM1 in conformity with the variations in PVT of the first predriver 210 shown in FIG. 2. The data output driver circuit according to one embodiment can be configured to include the second predriver control unit 155, which monitors the driving characteristics of the PMOS transistor (not shown) in conformity with the variations in PVT of the second predriver 220. For the sake of simplicity in explanation, only the first predriver control unit 105 will be described.

The first predriver control unit 105 can be configured to include a PVT sensing part 110, a voltage comparison part 120, and an output load control signal generation part 130.

The PVT sensing part 110 can be configured to sense an external voltage (VDD) and provide a sensed external voltage signal (DET). In detail, the PVT sensing part 110 can sense the external voltage (VDD) in response to an enable signal (EN), which is activated upon variations in PVT.

The PVT sensing part 110 can be configured to include a second NMOS transistor NM2, which can be manufactured through the same manufacturing process as the first NMOS transistor NM1 of the first predriver 210. The second NMOS transistor NM2 can be configured to include a gate, which receives the external voltage (VDD), a drain, which can be connected with an internal voltage (VINT), and a source, which can be connected with a third NMOS transistor NM3. The third NMOS transistor NM3 can have a gate, which receives the enable signal (EN), a drain, which is connected with the second NMOS transistor NM2, and a source, which is connected with the ground voltage (VSSQ).

Here, the enable signal (EN) can be a signal that can be activated upon variations in PVT. That is to say, the enable signal (EN) can be a signal which can be provided for a predetermined interval, for example, by an MRS resistor, so that PVT factors can be found upon variations in PVT.

Therefore, the PVT sensing part 110 can sense the external voltage (VDD) only for the predetermined interval during which the enable signal (EN) is activated. In other words, the first predriver control unit 105 according one embodiment can be a circuit part that is not always activated and instead can operate for a predetermined interval, for example, only upon variations in PVT. Because the drain of the second NMOS transistor NM2 of the PVT sensing part 110 is connected with the internal voltage (VINT), which is more stable than the external voltage (VDD), the change in driving capability of the second NMOS transistor NM2, which can be caused by the variations in PVT, can be more stably monitored. Meanwhile, a load resistor RL can be connected between the internal voltage (VINT) and the second NMOS transistor NM2.

While not shown in the drawings, the second predriver control unit 155 can sense the ground voltage (VSS) using the PMOS transistor, which can influence the slew rate of the pulldown signal (dn) of the second predriver 220. Thus, in one embodiment, the monitoring transistor can be manufactured through the same process as the driving transistor of the predriver 200, which can influence the slew rate of the pullup part (Pu) or the pulldown part (Pd) of the data output unit 300. Accordingly, the slew rate of the pullup signal (up) or the pulldown signal (dn) can be controlled by more dynamically conforming to the variations in PVT.

The voltage comparison part 120 can be configured to receive and digitize the sensed external voltage signal (DET) and provides comparison signals (com1), (com2) and (com3). More specifically, the voltage comparison part 120 can be configured to include a plurality of comparators 121 through 123, which can compare the sensed external voltage signal (DET) with the voltages distributed by predetermined resistors Rc1 through Rc4.

When the sensed external voltage signal (DET) is higher than the voltages distributed by the predetermined resistors Rc1 through Rc4, the comparators 121 through 123 can be configured to provide the comparison signals (com1) through (com3) of a first level, for example, a high level. Here, the predetermined resistors Rc1 through Rc4 can be resistors, which are preset to determine the digitized sections of the comparison signals (com1) through (com3). Therefore, the predetermined resistors Rc1 through Rc4, which define the digitized sections, can have the same values.

Meanwhile, in order to cause the comparison signals (com1) through (com3) to be precise, the digitized sections can be further subdivided. Accordingly, by using an increased number of predetermined resistors, the sections can be more precisely defined.

Referring to FIG. 3 with respect to the voltage comparison part 120, the voltage, which can be distributed by the first resistor Rc1 and the second through fourth resistors Rc2 through Rc4, can be provided to a node e. Thus, the first comparator 121 can be configured to receive and compare the sensed external voltage signal (DET) of a node d and the voltage signal of the node e. If the sensed external voltage signal (DET) is higher than the voltage signal of the node e, the first comparator 121 can provide the comparison signal (com1) of a first level, that is, a high level. In other words, if the driving capability of the second NMOS transistor NM2 is decreased due to the variations in PVT and the level of (DET) is higher than the voltage of the node e, according to the comparison result, the comparison signal (com1) of the first level, that is, the high level, can be provided.

If the sensed external voltage signal (DET) received by the first comparator 121 is lower than the signal of the node e (here, the signal of the node e is a voltage signal distributed by the first resistor Rc1 and the second through fourth resistors Rc2 through Rc4), according to the comparison result, the comparison signal (com1) of a second level, for example, a low level, can be provided.

Since the second and third comparators 122 and 123 operate in a similar manner, detailed description thereof will be omitted herein.

Again referring to FIG. 3, the output load control signal generation part 130 can be configured to receive and latch the comparison signals (com1) through (com3) and to provide the plurality of output load control signals (EN<0:2>) and (/EN<0:2>).

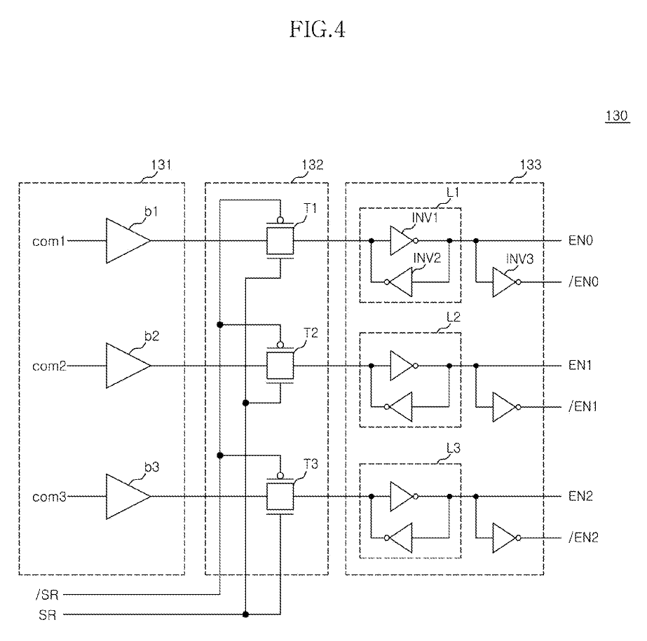

FIG. 4 is a detailed circuit diagram illustrating an output load control signal generation part 130 that can be included in the diagram illustrated in FIG. 3. Referring to FIG. 4, the output load control signal generation part 130 can be configured to include buffer unit 131, transmission unit 132 and signal control unit 133.

The buffer unit 131 can be configured to include first through third buffers b1 through b3. The respective buffers b1 through b3 can be configured to receive and buffer the comparison signals (com1) through (com3). The buffered signals can be transmitted or intercepted by the transmission unit 132. The transmission unit 132 can be configured to include first through third transmission gates, T1 through T3. The respective transmission gates, T1 through T3, can be controlled by transmission gate enable signals (SR) and (/SR). Here, similar to the above-described enable signal (EN), the transmission gate enable signals (SR) and (/SR) can be signals that are activated when monitoring variations in PVT and are delayed by a predetermined time from the enable signal (EN). Namely, the transmission gate enabled signals (SR) and (/SR) can be signals that are activated after the PVT sensing part 110 can sense the external voltage (VDD) and that the comparison operation is sufficiently implemented in the voltage comparison part 120.

Accordingly, when the transmission unit 132 receives signals transmitted after being buffered, the transmission unit 132 can turn on the first through third transmission gates T1 through T3 only for predetermined sections, and thereafter, can provide the output load control signals (EN<0:2>) and (/EN<0:2>) capable of controlling the slew rate.

In detail, as the transmission unit 132 is controlled by the activated transmission gate enable signals (SR) and (/SR), the first through third transmission gates T1 through T3 are turned on. Then, the transmission unit 132 can provide the buffered comparison signals (com1) through (com3) to the signal control unit 133. The signal control unit 133 can receive and latch the comparison signals (com1) through (com3), which are provided after being buffered.

The signal control means 133 includes a plurality of latch unit L1 through L3. Each of the latch units L1 through L3 can include first and second inverters INV1 and INV2. The respective latch units L1 through L3 can receive the signals provided by the transmission unit 132 when the transmission unit 132 is activated. However, the latch units L1 through L3 can be configured to continually latch the received signals while the transmission means 132 is inactivated. Hence, the signal control means 133 can provide the signals received by the latch units L1 through L3 as the pullup output load control signals (/EN<0:2>) or the pulldown output load control signals (EN<0:2>), which are inverted by an inverter INV3.

In this way, the output load control signal generation part 130 can receive the comparison signals (com1) through (com3) and provides the pullup output load control signals (/EN<0:2>) or the pulldown output load control signals (EN<0:2>).

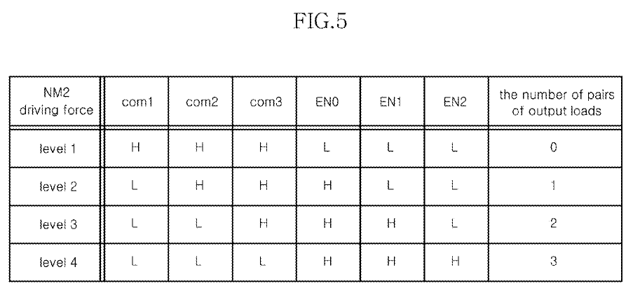

FIG. 5 is a table illustrating the number of pairs of activated output loads 216 through 218 of the predriver 210, which can be controlled in conformity with the driving capability of the second NMOS transistor NM2.

Levels 1 through 4 represent a driving capability of a second NMOS transistor NM2. It means that the level 2 has greater driving capability than the level 1. Thus, in one embodiment, the level 4 means that the driving capability of the second NMOS transistor NM2 can be considerably large. When the driving capability of the second NMOS transistor NM2 is large, the comparison signals (com1) through (com3) having the first level as the high level are provided. When the driving capability of the second NMOS transistor NM2 is small, the comparison signals (com1) through (com3) having the second level as the low level are provided. That is to say, the levels of comparison signals (com1) through (com3) can be adjusted using the driving capability of the second NMOS transistor NM2, which can change depending upon the variations in PVT. Also, depending upon the levels of the comparison signals (com1) through (com3), the output load control signals (EN<0:2>) and (/EN<0:2>) can be selectively controlled.

In other words, if the second NMOS transistor NM2 has small driving capability in conformity with the variations in PVT, the first NMOS transistor NM1 of the first predriver 210 can also have small driving capability. Therefore, as the driving capability of the first NMOS transistor NM1 is reflected, it is not necessary to separately control the pairs of output loads 216 through 218 of the first predriver 210 to adjust the slew rate. However, if the second NMOS transistor NM2 has large driving capability, since the driving capability of the first NMOS transistor NM1 of the first predriver 210 will also be large, the pairs of output loads 216 through 218 can be selectively activated to adjust the slew rate in conformity with the driving capability of the first NMOS transistor NM1 of the first predriver 210. Namely, the slew rate can be adjusted in conformity with the driving capability of the first NMOS transistor NM1 of the first predriver 210.

The operations of the data output driver circuit according to one embodiment will be described below with reference to FIGS. 2 through 5.

The third NMOS transistor NM3 can be configured to turn on for a predetermined time for sensing the external voltage (VDD), by the enable signal (EN), which can be activated upon variations in PVT. Further, depending upon the driving capability of the second NMOS transistor NM2, which can sense the external voltage (VDD), the sensed external voltage signal (DET) is provided to the node d. The respective comparators 121 through 123 can receive the sensed external voltage signal (DET) and the respective voltages, which are distributed by the predetermined resistors Rc1 through Rc4.

For example, a case, in which the driving capability of the second NMOS transistor NM2 is considerably large so the sensed external voltage signal (DET) is low, will be described below. In this case, the first through third comparators 121 through 123 can receive the sensed external voltage signal (DET), which is lower than the respective voltages distributed by the predetermined resistors Rc1 through Rc4. Therefore, the output values of the respective comparators 121 through 123 provide comparison signals (com1) through (com3), all of which can have the second level as the low level. In succession, the output load control signal generation part 130 can receive the comparison signals (com1) through (com3) having the second level as the low level, and provide inverted and activated pulldown output load control signals (EN<0:2>) having the high level.

Also, the output load control signal generation part 130 can be configured to provide the pulldown output load control signals (EN<0:2>) and the inverted and activated pullup output load control signals (/EN<0:2>) of the low level. Accordingly, the pairs of output loads 216 through 218 of the output load control part 215 of the first predriver 210 can all be turned on. Accordingly, the data (Din) input to the first NMOS transistor NM1 of the first predriver 210, which has considerably large driving capability, can be substantially adjusted in the slew rate thereof and can be provided as the pullup signal (up). That is, due to the fact that the pairs of output loads 216 through 218 of the output load control part 215 of the first predriver 210 can all turn on, it is possible to provide the pullup signal (up) which has a significantly slowed slew rate.

The situation in which the driving capability of the second NMOS transistor NM2 is considerably small, such that the sensed external voltage signal (DET) is high, will be described below. In this case, since the first through third comparators 121 through 123 can receive the sensed external voltage signal (DET) which can be higher than the respective voltages distributed by the predetermined resistors Rc1 through Rc4, the output values of the respective comparators 121 through 123 provide comparison signals (com1) through (com3) all of which have the first level as the high level.

Therefore, the output load control signal generation part 130 can receive the inactivated comparison signals (com1) through (com3) having the high level, and can provide inverted and inactivated pulldown output load control signals (EN<0:2>) of the low level. Also, the output load control signal generation part 130 can provide the pulldown output load control signals (EN<0:2>) and the inverted and activated pullup output load control signals (/EN<0:2>) of the high level. Accordingly, the pairs of output loads 216 through 218 of the output load control part 215 of the first predriver 210 can all be turned off, and the data (Din) inputted to the first NMOS transistor NM1 of the first predriver 210, which has considerably small driving capability, can be substantially adjusted in the slew rate thereof and can be provided as the pullup signal (up). That is, due to the fact that the pairs of output loads 216 through 218 of the output load control part 215 of the first predriver 210 are all turn off, it is possible to provide the pullup signal (up), which is not substantially adjusted in the slew rate thereof.

Also, in a similar manner, depending upon the driving capability of the second NMOS transistor NM2, the number of pairs of output loads 216 through 218 can be selectively controlled in response to the digitized comparison signals (com1) through (com3). That is, depending upon the comparison result of the voltage comparison part 120, the slew rate of the predriver 200 can be adjusted in a digitized unit.

Meanwhile, while not shown in the drawings, it will readily appreciate that the second predriver 220 can also be adjusted in the slew rate thereof in the same manner by selectively controlling pairs of output loads.

As described above, in the data output driver circuit according to the embodiments described herein, by adjusting the slew rate of an output signal from the predriver, it is possible to provide the output signal on which the variations in PVT are reflected. That is to say, by the fact that the transistor manufactured under the same conditions as the driving transistor of the predriver can be used as a transistor for monitoring, depending upon the result of monitoring, the slew rate can be adjusted in a digitized unit. In other words, it is possible to control a slew rate such that the driving capability of the driving transistor of the predriver can be dynamically reflected.

By comparing the driving capability of a transistor for sensing an external voltage upon variations in PVT, the slew rate of an output data signal can be improved. That is to say, an external voltage, which varies in conformity with the variations in PVT, can be sensed by a driving transistor, which is substantially the same as the driving transistor included in a data output unit. The sensed external voltage and a predetermined voltage value can be compared with each other, and depending upon a comparison result, the activation of pairs of output loads can be controlled. In this way, the slew rate of an output data signal can be improved. By using a simple external voltage sensing method, it is possible to provide an output data signal which can be controlled in slew rate in conformity with variations in PVT.

While certain embodiments have been described above, it will be understood that the embodiments described are by way of example only. Accordingly, the apparatus and methods described herein should not be limited based on the described embodiments. Rather, the apparatus and methods described herein should only be limited in light of the claims that follow when taken in conjunction with the above description and accompanying drawings.

What is claimed is:

1. A data output driver circuit comprising:
a predriver control unit is configured to generate a plurality of pullup output load control signals and a plurality of pulldown output load control signals depending upon a sensed external voltage; and
a predriver is configured to output a signal by adjusting a slew rate of an inputted data in response to the plurality of pullup output load control signals and the plurality of pulldown output load control signals.

2. The data output driver circuit of claim 1, wherein the predriver control unit comprises:
a PVT sensing part including a transistor is configured to sense the external voltage;
a voltage comparison part is configured to digitize the sensed external voltage and providing comparison signals; and
an output load control signal generation part is configured to receive and latch the comparison signals and providing the plurality of output load control signals.

3. The data output driver circuit of claim 2, wherein, when the PVT sensing part comprises an NMOS transistor, an external driving voltage is sensed in response to an enable signal which is activated upon variations of PVT.

4. The data output driver circuit of claim 2, wherein, when the PVT sensing part comprises a PMOS transistor, an external ground voltage is sensed in response to an enable signal which is activated upon variations of PVT.

5. The data output driver circuit of claim 2, wherein the voltage comparison part comprises a plurality of comparators is configured to compare the sensed external voltage with a voltage distributed by predetermined resistors.

6. The data output driver circuit of claim 5, wherein the voltage comparison part provides comparison signals of a first level when the sensed external voltage is greater than the voltage distributed by the predetermined resistors.

7. The data output driver circuit of claim 5, wherein the voltage comparison part provides comparison signals of a second level when the sensed external voltage is less than the voltage distributed by the predetermined resistors.

8. The data output driver circuit of claim 2, wherein the output load control signal generation part generates pulldown output load control signals which have a level inverted from the level of the comparison signals.

9. The data output driver circuit of claim 2, wherein the output load control signal generation part generates pullup output load control signals which have the same level as the comparison signals.

10. The data output driver circuit of claim 8, wherein the output load control signal generation part comprises transistors, as the driving capability of the transistors is increased, the number of the pulldown output load control signals and the pullup output load control signals, which are activated in response to the comparison signals, is increased.

11. The data output driver circuit of claim 1, wherein the predriver comprises a pullup load part and a pulldown load part, and the pullup load part and the pulldown load part are oppositely positioned to each other.

12. The data output driver circuit of claim 11, wherein each of the pullup and pulldown load parts comprises a plurality of switching elements which are connected in parallel with one another, and the switching elements of the pullup and pulldown load parts which are simultaneously controlled to be activated as pairs of output loads and are connected to common nodes.

13. The data output driver circuit of claim 11, wherein the pulldown load part is selectively activated in response to the plurality of pulldown output load control signals.

14. The data output driver circuit according to claim 11, wherein the pullup load part is selectively activated in response to the plurality of pullup output load control signals.

15. A data output driver circuit comprising:
a predriver control unit is configured to sense an external voltage using a transistor capable of monitoring driving characteristics of a predriver and generate a plurality of pullup output load control signals and a plurality of pulldown output load control signals depending upon the sensed external voltage; and
the predriver is configured to change an output load depending upon the driving characteristics in response to the plurality of pullup output load control signals and the plurality of pulldown output load control signals, and output a signal by adjusting a slew rate of an inputted data.

16. The data output driver circuit of claim 15, wherein the predriver control unit comprises:
a PVT sensing part including a transistor for sensing the external voltage;
a voltage comparison part is configured to digitize the sensed external voltage and providing comparison signals; and
an output load control signal generation part is configured to receive and latching the comparison signals and providing the plurality of output load control signals.

17. The data output driver circuit of claim 16, wherein, when the PVT sensing part comprises an NMOS transistor, an external driving voltage is sensed in response to an enable signal which is activated upon variations of PVT.

18. The data output driver circuit of claim 16, wherein, when the PVT sensing part comprises a PMOS transistor, an external ground voltage is sensed in response to an enable signal which is activated upon variations of PVT.

19. The data output driver circuit of claim 16, wherein the voltage comparison part comprises a plurality of comparators for comparing the sensed external voltage with a voltage distributed by predetermined resistors.

20. The data output driver circuit according to claim 19, wherein the voltage comparison part provides comparison signals of a first level when the sensed external voltage is greater than the voltage distributed by the predetermined resistors.

21. The data output driver circuit according to claim 19, wherein the voltage comparison part provides comparison signals of a second level when the sensed external voltage is less than the voltage distributed by the predetermined resistors.

22. The data output driver circuit of claim 16, wherein the output load control signal generation part generates pulldown output load control signals which have a level inverted from the level of the comparison signals.

23. The data output driver circuit according to claim 16, wherein the output load control signal generation part generates pullup output load control signals which have the same level as the comparison signals.

24. The data output driver circuit of claim 22, wherein the output load control signal generation part comprises transistors, as the driving capability of the transistors is increased, the number of the pulldown output load control signals and the pullup output load control signals, which are activated in response to the comparison signals, is increased.

25. The data output driver circuit according to claim 15, wherein the predriver comprises a pullup load part and a pulldown load part, and the pullup load part and the pulldown load part are oppositely positioned to each other.
